(19) United States
(12) Patent Application Publication
(10) Pub. No.: US 2024/0313056 A1
(43) Pub. Date: Sep. 19, 2024

(54) A GRAPHENE SUBSTRATE AND METHOD OF FORMING THE SAME

(71) Applicant: Paragraf Limited, Somersham (GB)

(72) Inventors: Sebastian DIXON, Somersham (GB); Jaspreet KAINTH, Somersham (GB); Ivor GUINEY, Somersham (GB); Thomas James BADCOCK, Somersham (GB)

(73) Assignee: Paragraf Limited, Somersham (GB)

(21) Appl. No.: 18/577,827

(22) PCT Filed: Jul. 4, 2022
(86) PCT No.: PCT/EP2022/068476

§ 371 Date: Jan. 9, 2024

(30) Foreign Application Priority Data
Jul. 12, 2021 (GB) 2110031.8
Mar. 11, 2022 (WO) PCT/EP2022/056398

(51) Int. Cl. H01L 29/16; H01L 21/02

(52) U.S. Cl. CPC H01L 29/1606; H01L 21/02376; H01L 21/02458; H01L 21/02483; H01L 21/02502; H01L 21/02527; H01L 21/0262

(57) ABSTRACT

There is provided a graphene substrate comprising: a graphene layer structure directly on a metal oxide layer, said metal oxide layer directly on a support layer; wherein the metal oxide layer has a thickness of less than 5 nm and is selected from the group consisting of Al₂O₃, HfO₂, MgO, MgAl₂O₄, Ta₂O₅, Y₂O₃, ZrO₂ and YSZ; and wherein the support layer is BN, AlN, GaN, SiC, diamond, or a combination thereof.

The present invention provides a graphene substrate which is one that comprises a graphene layer structure on a metal oxide layer. In particular, said metal oxide layer is directly on a support layer. More particularly, the support layer is boron nitride, aluminium nitride, gallium nitride, silicon carbide, diamond or a combination thereof. The present invention also provides a method of forming a graphene substrate. In particular, the method comprises providing a growth substrate comprising or consisting of a support layer formed of BN, AlN, GaN, SiC, diamond or a combination thereof, forming a metal oxide layer thereon followed by a graphene layer structure. More particularly, the metal oxide layer is formed by ALD and the graphene layer structure by CVD.

Graphene has received much attention as a two-dimensional material in view of its unique electronic properties and its applications in electronic devices. It is common in the art for graphene to be manufactured by techniques such as exfoliation or by CVD on catalytic metal substrates such as copper. The graphene produced by such methods is then transferred to electronic device compatible substrates such as silicon dioxide for the manufacture of said electronic devices.

It is also known in the art that graphene may be synthesised, manufactured, formed, directly on non-metallic surfaces of substrates. These include silicon, sapphire and III-V semiconductor substrates. The present inventors have found that the most effective method for manufacturing high-quality graphene, especially directly on such non-metallic surfaces, is that disclosed in WO 2017/029470. This publication discloses methods for manufacturing graphene; principally these rely on heating a substrate held within a reaction chamber to a temperature that is within a decomposition range of a carbon based precursor for graphene growth, introducing the precursor into the reaction chamber through a relatively cool inlet so as to establish a sufficiently steep thermal gradient that extends away from the substrate surface towards the point at which the precursor enters the reaction chamber such that the fraction of precursor that reacts in the gas phase is low enough to allow the formation of graphene from carbon released from the decomposed precursor. Preferably the apparatus comprises a showerhead having a plurality of precursor entry points or inlets, the separation of which from the substrate surface may be varied and is preferably less than 100 mm. The method of WO 2017/029470 is ideally performed using an MOCVD reactor. Whilst MOCVD stands for metal organic chemical vapour deposition due to its origins for the purposes of manufacturing semiconductor materials such as AlN and GaN from metal organic precursors such as AlMe₃ (TMAI) and GaMe₃ (TMGa), such apparatus and reactors are well known and understood to those skilled in the art as being suitable for use with non-metal organic precursors. MOCVD may be used synonymously with metal organic vapour phase epitaxy (MOVPE).

Whilst the method of WO 2017/029470 enables the production of high-quality graphene with excellent uniformity and a constant number of layers (as desired) across its whole area on the substrate without additional carbon fragments or islands, the strict requirements in the art of electronic device manufacture means that there remains a need to further improve the electronic properties of the graphene and to provide methods that are more reliable and more efficient for the industrial manufacture of graphene, particularly large area graphene on non-metallic substrates.

It is however known that electron-phonon coupling between graphene and the substrate can have a detrimental effect on the carrier mobilities when compared to the theoretical values for free standing graphene. Polar phonons are able to induce electric fields in adjacent layers which result in the remote phonon scattering of electrons in said layer. Such coupling is long range and may also be known as Fröhlich coupling.

Electron-phonon coupling has been studied both theoretically and experimentally, particularly in respect of substrates such as silicon dioxide. Nature Nanotechnology 3, 206-209 (2008) “Intrinsic and Extrinsic Performance Limits of Graphene Devices on SiO₂” and Phys. Rev. B 77, 195415 (2008) “Substrate limited electron dynamics in graphene” study the effects of polarisable substrates such as SiO₂ and SiC on the carrier dynamics in graphene.

Nature Nanotechnology 5, 722-726 (2010) “Boron nitride substrates for high-quality graphene electronics” and Appl. Phys. Lett. 115, 043104 (2019) “Role of remote interfacial phonons in the resistivity of graphene” are examples which demonstrate the benefits of hexagonal boron nitride (h-BN) as a promising substrate since the optical phonon modes of h-BN are much higher in energy than other dielectrics (such as SiO₂ and HfO₂). The energies of the relevant phonon modes are about twice as large as those in SiO₂. The prevalence of phonon modes of lower energy in the oxide substrates results in the remote phonon scattering and a larger resistivity in the graphene provided thereon (i.e. a reduction in carrier mobility).

US 2012/261640 A1 relates to an electronic device employing a graphene layer as a charge carrier layer, the graphene layer sandwiched between layers that are constructed of a material having a highly ordered crystalline structure and high dielectric constant, such as SiO₂, HfO₂ and Al₂O₃. In some embodiments, the graphene layer is provided on an interfacial layer rather than on the highly ordered crystalline material, the interfacial layer being a thin layer of dielectric, non-polar material. Suitable non-polar materials include polymers such as polyethylene, polypropylene and polystyrene.

US 2010/200839 A1 relates to substrates have a graphene layer grown thereon, and electro-optical integrated circuits formed in such a substrate. This document discloses aluminium oxide formed on a single crystal silicon substrate that has an average thickness of 10 nm or more and 500 nm or less—an average thickness of less than 10 nm is undesirable.

2015 10^{th} Spanish Conference on Electron Devices (CDE) “Monte Carlo modeling of mobility and microscopic charge transport in supported graphene” evaluates, by means of an ensemble Monte Carlo simulator, the influence of the underlying substrate on the mobility and electronic transport in graphene, specifically h-BN, SiC, SiO₂ and HfO₂.

There remains a need in the art for graphene provided on substrates having reduced electron-phonon coupling so as to improve the electronic properties of the graphene together with methods of forming graphene on suitable substrates. The inventors developed the present invention with the aim of addressing at least these problems.

In accordance with a first aspect of the present invention, there is provided a graphene substrate comprising:
a graphene layer structure directly on a metal oxide layer, said metal oxide layer directly on a support layer;
wherein the metal oxide layer has a thickness of less than 5 nm and is selected from the group consisting of Al₂O₃, HfO₂, MgO, MgAl₂O₄, Ta₂O₅, Y₂O₃, ZrO₂ and YSZ; and
wherein the support layer is BN, AlN, GaN, SiC, diamond, or a combination thereof.

In a further aspect there is provided a method of forming a graphene substrate, the method comprising:
providing a growth substrate comprising or consisting of a support layer formed of BN, AlN, GaN, SiC, diamond, or a combination thereof;
forming a metal oxide layer on the support layer by ALD, wherein the metal oxide layer has a thickness of less than 5 nm and is selected from the group consisting of Al₂O₃, HfO₂, MgO, MgAl₂O₄, Ta₂O₅, Y₂O₃, ZrO₂ and YSZ; and forming a graphene layer structure on the metal oxide layer by CVD.

The present disclosure will now be described further. In the following passages, different aspects/embodiments of the disclosure are defined in more detail. Each aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous.

The present invention relates to a graphene substrate per se and a method of forming a graphene substrate comprising forming graphene. Forming may be considered synonymous with synthesising, manufacturing, producing and growing. Graphene is a very well-known two-dimensional material referring to an allotrope of carbon comprising a single layer of carbon atoms in a hexagonal lattice. Graphene, as used herein, refers to one or more layers of graphene. Accordingly, the present invention relates to the formation of a monolayer of graphene as well as multilayer graphene (which may be termed a graphene layer structure). Graphene, as used herein, refers to a graphene layer structure, preferably having from 1 to 10 monolayers of graphene. In many subsequent applications of a graphene substrate, one monolayer of graphene is particularly preferred. Accordingly, the graphene substrate preferably comprises a graphene monolayer directly on a metal oxide layer. The graphene manufactured in the method disclosed herein is preferably monolayer graphene. Nevertheless, multilayer graphene is preferable for other applications and 2 or 3 layers of graphene may be preferred. As described herein, it is particularly preferred that the graphene is obtainable, preferably obtained by CVD (where CVD refers to the CVD growth of graphene directly onto the metal oxide layer).

A graphene substrate will be understood as a substrate comprising graphene and suitable for subsequent use. Particularly, the graphene substrate is suitable for use in preparing graphene based electronic devices. As used herein, the term substrate may be used to refer to a material suitable for the deposition of another layer thereon. The term substrate is typically synonymous with a wafer. Accordingly, each of the support layer and metal oxide can each independently be referred to as a substrate.

The graphene substrate further comprises a metal oxide layer and a support layer. The graphene layer structure is provided directly on the metal oxide layer. That is, there is no intervening layer or material and one surface of the graphene is in direct substantially continuous contact with the surface of the metal oxide layer. It will be appreciated that the graphene may comprise wrinkles which are a physical deformation of the graphene away from the surface of the substrate. The graphene is nevertheless preferably a single continuous sheet/layer of carbon atoms (or multiple individually stacked continuous sheets/layers where the graphene is multilayer graphene). Similarly, the metal oxide layer is provided directly on the support layer.

The inventors have found that a thin metal oxide layer may be provided across a support layer so as to provide a preferred surface for the formation of graphene, particularly by CVD, even more particularly by CVD in accordance with WO 2017/029470. The inventors have found that a thin metal oxide layer, despite being made of a material which is known to exhibit the necessary phonon modes of appropriate energy to couple with the electrons in an adjacent layer, enables graphene to be provided closely adjacent to a support layer made of material which exhibits a desirable phonon band structure which results in reduced electron-phonon coupling. Accordingly, electron-phonon coupling is not appreciably observed where a sufficiently thin metal oxide layer is provided. The inventors have found that a metal oxide layer having a thickness of less than 5 nm is sufficient to provide such an advantage. Even more preferably, the metal oxide layer has a thickness of less than 4 nm.

Whilst it is preferable to have a thickness a small as possible in view of the potential for coupling between the metal oxide and graphene, a sufficiently thick metal oxide layer is needed to provide an improvement in the growth of graphene directly on the layer by CVD. The inventors have found that a metal oxide layer thickness of at least 0.5 nm is sufficient, though preferably the thickness is at least 1 nm, more preferably at least 2 nm. As a result, the metal oxide layer preferably has a thickness of from 0.5 nm to 5 nm, 1 nm to 4 nm, and most preferably from 2 nm to 4 nm.

The metal oxide layer is formed from a material selected from the group consisting of Al₂O₃, HfO₂, MgO, MgAl₂O₄, Ta₂O₅, Y₂O₃, ZrO₂ and YSZ. That is, the layer consists of said material. The inventors have found that such metal oxides are particularly suitable for the growth of graphene directly thereon by CVD. Without wishing to be bound by theory, the inventors have found that these materials have sufficiently low carbon solubility such that during the high temperatures of CVD, high-quality uniform graphene may be grown without the defects which can be present when grown directly on materials such as those of the support layer. Accordingly, the use of a metal oxide layer provides advantages for CVD grown graphene despite the anticipated drawbacks regarding electron-phonon coupling. The inventors have nevertheless overcome this problem with the use of a sufficiently thin metal oxide layer.

As will be appreciated, the stoichiometries of the metal oxides need not be precise (e.g. Al₂O₃). As is known in the art, the stoichiometry of such materials may vary. For example, alumina may be referred to as AlOₓ wherein x is about 3/2. Preferably, the metal oxide layer is Al₂O₃, HfO₂ or YSZ which are materials which allow for the formation of particularly high-quality graphene.

In the graphene substrate, the support layer is formed of a material selected from the group consisting of BN, AlN, GaN, SiC, diamond, or, optionally, a combination thereof. That is, the layer consists of said material. The inventors have identified such materials as those which have a desirable phonon band structure wherein the active phonon modes and associated symmetries and energies are such that electron-phonon coupling is advantageously reduced relative to other suitable substrates for electronic device manufacture, i.e. dielectric and/or semiconducting substrates. Accordingly, whilst the inventors have identified BN, AlN, GaN, SiC, diamond, and combinations thereof as suitable materials which demonstrate such advantageous properties, equivalent materials can be identified by a skilled person by matter of routine experimentation such that the technical benefit of the present invention may be realised and exploited using such an equivalent. Such materials may be referred to a “low phonon density” materials in view of the reduced density of available relevant phonon modes to couple with the corresponding electrons in the adjacent graphene.

Preferably, the support layer is formed of BN, AlN, GaN, or a combination thereof. These materials have particularly low phonon densities so as to not inhibit the mobility of the overlying graphene. Preferably, BN is hexagonal boron nitride (i.e. h-BN) though cubic boron nitride may also be employed (i.e. c-BN). AlN and GaN are known to crystallise in cubic space groups. Most preferably, the support layer is formed from (consists essentially of) AlN.

Whilst it is known that graphene may be provided directly on “low phonon density” materials such a boron nitride, and on “high phonon density” materials such as SiO₂ and HfO₂, there has been no need in the art to combine such materials as described herein to provide a multilayer substrate. Graphene in the art is often provided by growth on a copper substrate and transferred by a polymer (typically PMMA) directly onto the desired substrate. Whilst the present inventors sought to manufacture graphene directly on the desirable low phonon density materials by CVD, the carbon solubility in these materials, and/or the formation of strong covalent bonds (such as Si—C bonds when grown on SiC) inhibits the formation of the high uniformity required for graphene based electronic applications. Defects such as these introduce a source of charge scattering which reduces carrier mobility. These problems do not arise when graphene is transferred onto substrates surfaces as is typical in the art. On the other hand, physical transfer of graphene, usually from copper, introduces numerous defects which negatively impacts the electronic properties of graphene. Furthermore, such processing is not suitable for large scale manufacture (such as on CMOS substrates in fabrication plants). Unintentional doping, particularly from the catalytic metal substrates together with the etching solutions, also results in the production of graphene which is not sufficiently consistent from sample to sample as is required for commercial production.

The inventors were surprised to find that a thin metal oxide layer was sufficient to allow for the formation of high quality graphene directly by CVD yet did not introduce undesirable electron-phonon coupling which would otherwise reduce carrier mobility.

Preferably, the support layer has a thickness of at least 5 nm, preferably at least 15 nm, more preferably at least 50 nm. In some embodiments, the support layer preferably has a thickness of at least 100 nm. In other embodiments, the support layer may have a thickness of at least 2 nm, for example, where the metal oxide layer is especially thin. It is generally preferred that the metal oxide layer is no thicker than the support layer.

Preferably, the support layer is provided on a wafer. The wafer underlying the combination of support layer, metal oxide layer and graphene is not particularly limited. Preferably the wafer is a sapphire or silicon wafer. As will be appreciated, a silicon wafer includes a “pure” silicon wafer (essentially consisting of silicon, doped or undoped) or what may be referred to as a CMOS wafer which includes additional associated circuitry.

The method of the present invention comprises providing a growth substrate comprising or consisting of a support layer formed of BN, AlN, GaN, SiC, diamond or a combination thereof. The growth substrate preferably further comprises a wafer which is preferably a sapphire or silicon wafer.

In some preferred embodiments, the method further comprises etching away or detaching the wafer after forming the graphene layer structure. The wafer provides support for the growth of graphene in a CVD reaction chamber, however, the wafer may be removed by etching or detachment so as to reduce the thickness of the graphene substrate which is preferable for electronic device applications.

The method further comprises forming a metal oxide layer on the support layer by ALD, wherein the metal oxide layer has a thickness of less than 5 nm and is selected from the group consisting of Al₂O₃, HfO₂, MgO, MgAl₂O₄, Ta₂O₅, Y₂O₃, ZrO₂ and YSZ.

The inventors have found that formation of metal oxide layers by ALD is particularly beneficial for providing highly conformal (uniform thickness) layers which is essential when forming such thin layers (as low as 0.5 nm thick). As is known in the art, ALD comprises the sequential introduction of at least two chemical precursors (for example ozone and trimethylaluminium so as to form aluminium oxide though other suitable materials for the metal oxides described herein are well known). The thickness of the layer may be controlled by varying the number of such cycles in view of the self-limiting nature of ALD growth.

The method further comprises forming a graphene layer structure on the metal oxide layer by CVD. CVD refers generally to a range of chemical vapour deposition techniques, each of which involve vacuum deposition to produce thin film materials such as two-dimensional crystalline materials like graphene. Volatile precursors, those in the gas phase or suspended in a gas, are decomposed to liberate the necessary species to form the desired material, carbon in the case of graphene.

Preferably, the method involves forming graphene by thermal CVD such that decomposition is a result of heating the precursor. Preferably, the CVD reaction chamber used in the method disclosed herein is a cold-walled reaction chamber wherein a heater coupled to the substrate is the only source of heat to the chamber. As will be appreciated, the substrate refers to the support layer and metal oxide layer, together with the underlying wafer where present.

In a particularly preferred embodiment, the CVD reaction chamber comprises a close-coupled showerhead having a plurality, or an array, of precursor entry points. Such CVD apparatus comprising a close-coupled showerhead may be known for use in MOCVD processes. Accordingly, the method may alternatively be said to be performed using an MOCVD reactor comprising a close-coupled showerhead. In either case, the showerhead is preferably configured to provide a minimum separation of less than 100 mm, more preferably less than 25 mm, even more preferably less than 10 mm, between the surface of the substrate and the plurality of precursor entry points. As will be appreciated, by a constant separation it is meant that the minimum separation between the surface of the substrate and each precursor entry point is substantially the same. The minimum separation refers to the smallest separation between a precursor entry point and the substrate surface (i.e. the surface of the metal oxide layer). Accordingly, such an embodiment involves a “vertical” arrangement whereby the plane containing the precursor entry points is substantially parallel to the plane of the substrate surface.

The precursor entry points into the reaction chamber are preferably cooled. The inlets, or when used, the showerhead, are preferably actively cooled by an external coolant, for example water, so as to maintain a relatively cool temperature of the precursor entry points such that the temperature of the precursor as it passes through the plurality of precursor entry points and into the reaction chamber is less than 100° C., preferably less than 50° C.

Preferably, a combination of a sufficiently small separation between the substrate surface and the plurality of precursor entry points and the cooling of the precursor entry points, coupled with the heating of the substrate to with a decomposition range of the precursor, generates a sufficiently steep thermal gradient extending from the substrate surface to the precursor entry points to allow graphene formation on the substrate surface. As disclosed in WO 2017/029470, very steep thermal gradients may be used to facilitate the formation of high-quality and uniform graphene directly on non-metallic substrates, preferably across the entire surface of the substrate. The substrate may have a diameter of at least 5 cm (2 inches), at least 15 cm (6 inches) or at least 30 cm (12 inches). Particularly suitable apparatus for the method described herein include an Aixtron® Close-Coupled Showerhead® reactor and a Veeco® TurboDisk reactor.

Consequently, in a particularly preferred embodiment wherein the method of the present invention involves using a method as disclosed in WO 2017/029470, the method comprises:
providing a substrate on a heated susceptor in a close-coupled reaction chamber, the substrate comprising a support layer and metal oxide layer, the close-coupled reaction chamber having a plurality of cooled inlets arranged so that, in use, the inlets are distributed across the substrate and have constant separation from the surface of the substrate (i.e. the metal oxide layer);
cooling the inlets to less than 100° C. (i.e. so as to cool the precursor);
introducing a precursor in a gas phase and/or suspended in a gas through the inlets and into the CVD reaction chamber to thereby decompose the precursor and form graphene on the metal oxide layer of the substrate; and
heating the susceptor to a temperature of at least 50° C. in excess of a decomposition temperature of the precursor, to provide a thermal gradient between the substrate surface and inlets that is sufficiently steep to allow the formation of graphene from carbon released from the decomposed precursor;
wherein the constant separation is less than 100 mm, preferably less than 25 mm, even more preferably less than 10 mm.

Preferably, the method further comprises forming one or more further layers on the graphene layer structure. Preferably this comprises forming a further metal oxide layer on the graphene layer structure by ALD, wherein the further metal oxide layer has a thickness of less than 5 nm and is selected from the group consisting of Al₂O₃, HfO₂, MgO, MgAl₂O₄, Ta₂O₅, Y₂O₃, ZrO₂ and YSZ. Equally, the method preferably then further comprises forming a further layer on the further metal oxide layer, wherein the further layer is BN, AlN, GaN, SiC, diamond, or a combination thereof.

In a further aspect there is provided an electrical device comprising the graphene substrate as described herein or the graphene substrate obtainable by the method disclosed herein. That is, an electrical device may be manufactured from a graphene substrate thereby incorporating a graphene layer structure directly on a metal oxide layer, said metal oxide layer directly on a support layer as described herein. Further steps for forming electrical devices are known in the art and may include patterning, such as by photolithography, laser and/or plasma etching, and/or deposition of additional layers and materials such a dielectric layers and/or metal ohmic contacts.

An electrical device comprising such a graphene substrate may be improved over prior art devices in view of the advantageous properties afforded by the graphene, in particular an improvement in carrier mobility. For example, an electro-optic modulator is one preferred electrical device which may benefit from greater carrier mobility. In particular, an electro-optic modulator comprising the graphene substrate may operate with greater bandwidth. Other preferred electric devices include transistors (i.e. graphene transistors) such as radio frequency graphene field effect transistors (RF GFETs) which rely on high carrier mobilities to switch “on” and “off” at such high frequencies. Biosensors are also preferred electrical devices which benefit from the higher mobility of graphene due to the associated reduction in sheet resistance which reduces the power required for operation. Another particularly preferred electrical device is a Hall effect sensor. The sensitivity of such devices may be improved with higher carrier mobilities.

### FIGURES

The present invention will now be described further with reference to the following non-limiting Figures, in which:

FIG. 1 is a plot of the graphene mobility as a function of the number of ALD cycles.

FIG. 2 is a plot of carrier scattering time as a function of the number of ALD cycles.

FIG. 3 is a Raman spectrum, and FIG. 4 an AFM image, of graphene grown directly on AlN.

FIG. 5 is a Rama spectrum, and FIG. 6 an AFM image, of graphene grown on the AIOₓ layer of an AIOₓ/AlN stack.

FIG. 7 is a cross-section of an electrolyte gated field effect transistor comprising an inventive graphene substrate.

FIGS. 8 to 12 are each a plot of current vs gate voltage for a transistor as shown in FIG. 7.

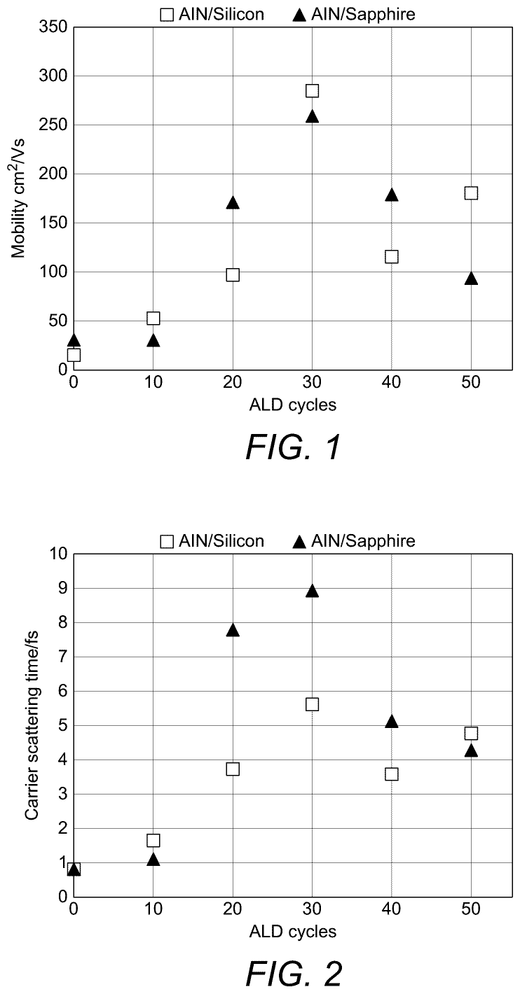

The data illustrated in FIGS. 1 and 2 are obtained from four graphene substrates in accordance with the present invention. The graphene substrates comprise a sapphire wafer having an AlN support layer thereon. An aluminium oxide layer is then formed at varying thickness by varying the number of cycles during the atomic layer deposition. Graphene is then formed thereon by CVD in accordance with the method described herein.

FIG. 1 demonstrates that an improvement in carrier mobility of the graphene formed on the metal oxide layer increase as the thickness of the metal oxide increases. The thickness of metal oxide layer (in nm) is approximately 1/10 of the number of ALD cycles. Despite the possible reduction in carrier mobility resulting from electron-phonon coupling, the inventors have found that a metal oxide layer that is less than 5 nm can give rise to improved carrier mobilities. The inventors have found that from 2 nm to 4 nm provide an optimum thickness with regards to carrier mobility.

FIG. 2 similarly demonstrates an improvement in the carrier scattering time as the thickness of the metal oxide layer increases up to about 3 nm at which point the increased thickness results in a reduction of the carrier scattering time. Accordingly, from 1 to 4 nm, preferably 2 nm to 3 nm, provides an optimum thickness with regards to carrier scattering time.

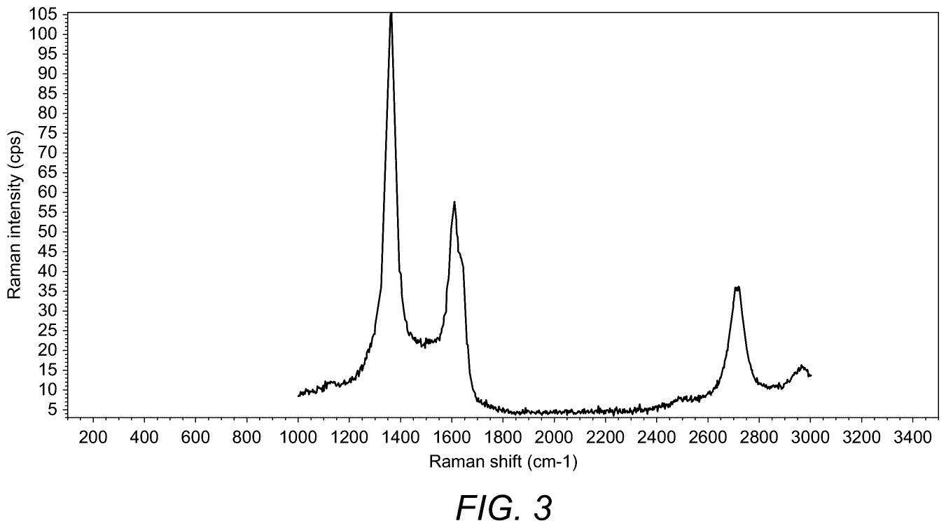

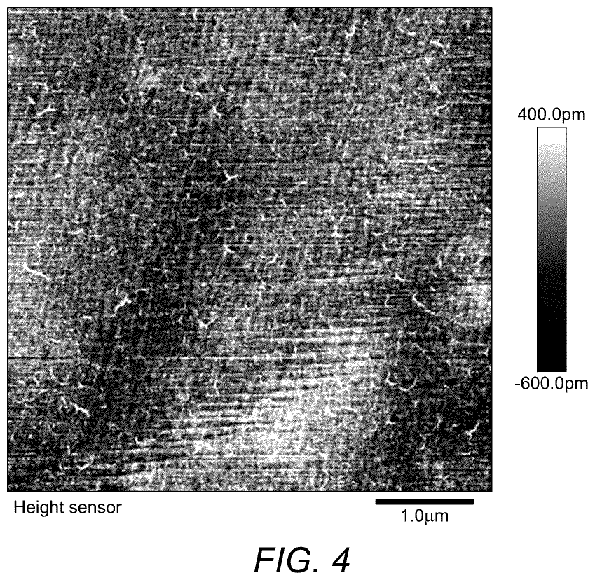

FIG. 3 is a Raman spectrum of graphene grown directly on AlN using a method in accordance with the Example with the exception that the ALD step of metal oxide growth is omitted. FIG. 4 is an AFM image of the same sample.

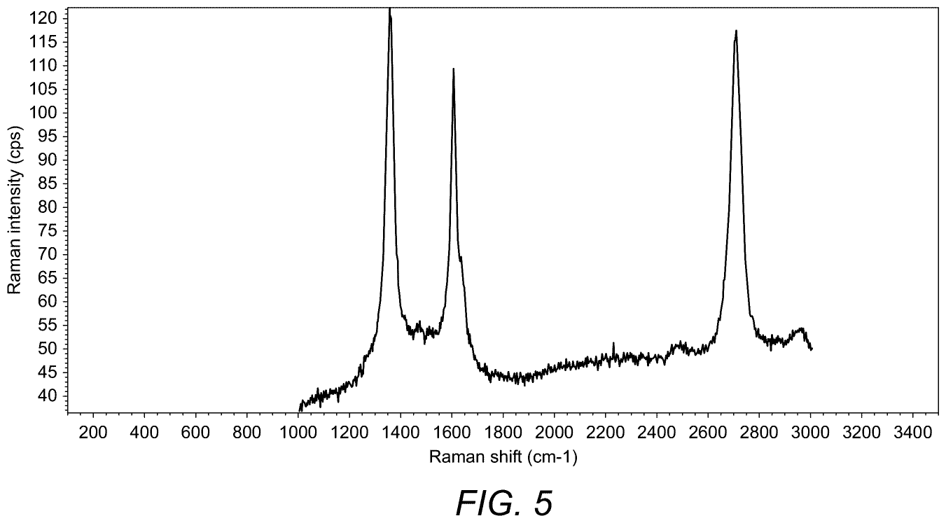

FIG. 5 is a Raman spectrum of graphene grown on the AlOₓ layer of an AIOₓ/AlN stack in accordance with the Example. FIG. 6 is an AFM image of the same sample.

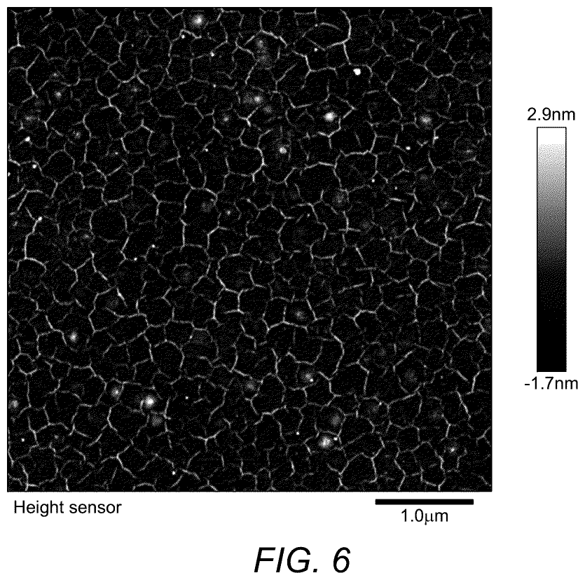

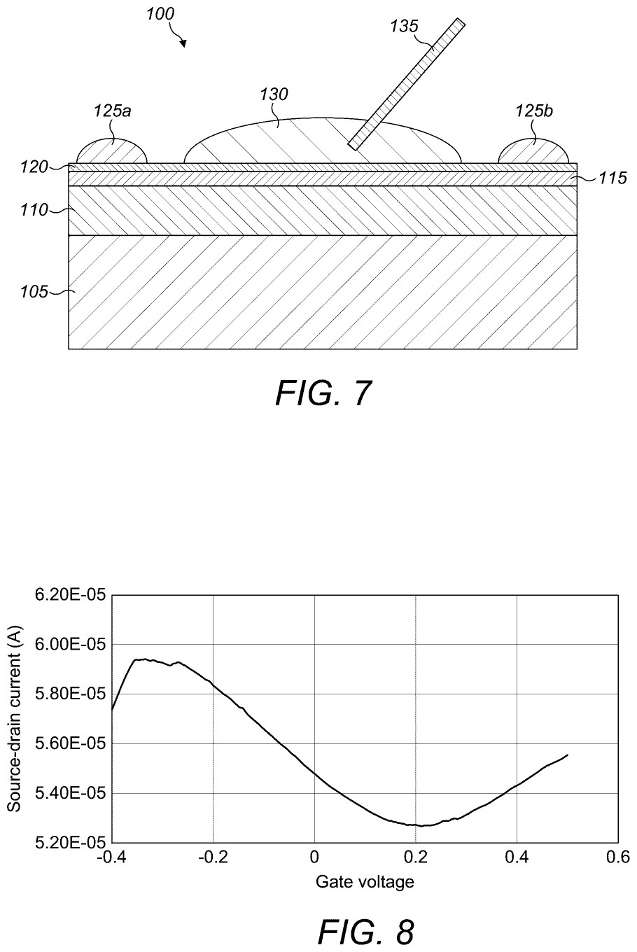

FIG. 7 is a schematic cross-section of an electrolyte gated GFET 100 manufactured according to the Example described herein. The transistor 100 comprises a graphene substrate according to the present invention. The graphene substrate is formed of a sapphire wafer 105, a 100 nm to 250 nm thick layer of aluminium nitride 110 and a about a 3 nm thick layer of aluminium oxide 115 thereon with a final graphene monolayer 120 across the surface of the aluminium oxide 115.

The transistor 100 further comprises painted silver (Ag) contacts 125a, 125b painted onto the surface of the graphene monolayer 120 so as to leave an exposed surface of the graphene monolayer therebetween that may receive an electrolyte 130. Contacts 125a 125b serve as source and drain electrodes of the transistor. In use, the electrolyte 130, for example a 100 mM potassium chloride (KCl) electrolyte, is deposited onto the surface of the graphene monolayer 120 and a conventional silver/silver chloride (Ag/AgCl) pellet probe 135 is immersed into the electrolyte and used as a gate electrode to supply a gate voltage.

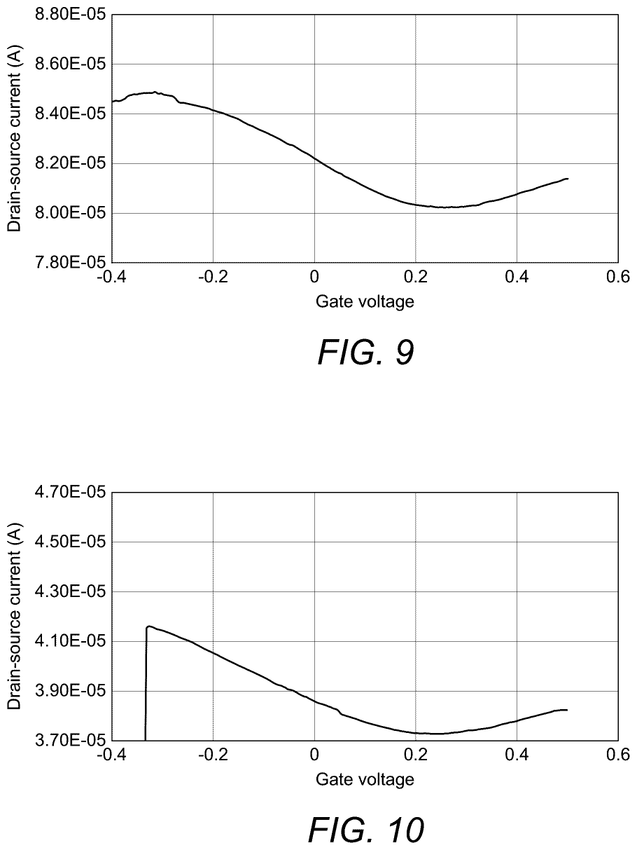

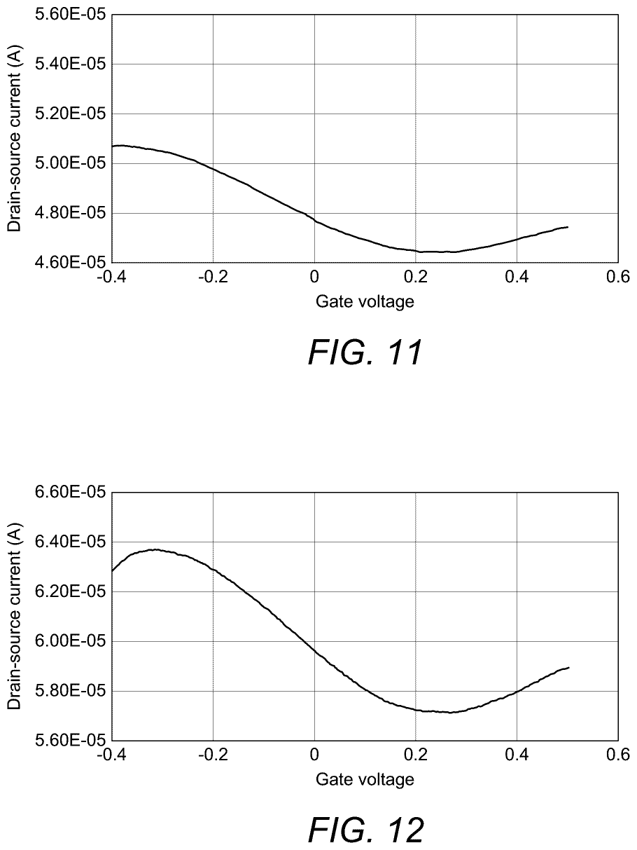

FIGS. 8 to 12 each plot current vs gate voltage for a plurality of electrolyte gated GFETs 100 manufactured on a single common sapphire wafer. For each transistor, the gate voltage is varied from −0.4 V to +0.6 V and the drain-source current (A) measured (with a drain voltage of 40 mV). For each transistor, the drain-source current is plotted over a range of 10 μA. These results show that each transistor is capable of being gated with a sensible Dirac gate voltage.

### EXAMPLE

The growth substrate comprising or consisting of a support layer is placed into an ALD chamber for metal oxide (MOₓ) growth. In two Examples described herein, the growth substrate consists of an aluminium nitride support layer on either a silicon or sapphire wafer. The thickness of the aluminium nitride layer may be between 100 nm and 250 nm. The substrate is held in the chamber at the deposition temperature of 150° C. under a vacuum of approximately 220 mTorr (about 27 Pa) with a nitrogen gas flow of 27 sccm to equilibrate the chamber temperature and pressure, as well as desorb any moisture from the sample surface. Al₂O₃ is then deposited using trimethyl aluminium (TMAI) and either deionised water (DI H₂O) or ozone (O₃) as the metalorganic and oxidant precursor, respectively, which are introduced into the deposition chamber using nitrogen as both the carrier and purge gas. The precursors are pulsed into the chamber in a 3:2 ratio, with pulse times of 0.6 seconds and purge times of 20 and 18 or 25 seconds for TMAI and DI H₂O or O₃, respectively. Films are deposited at 150° C. with varying numbers of cycles (between 5 and 100 cycles) depending on the desired film thickness.

The ALD-capped substrates are positioned upon a silicon carbide-coated graphite susceptor within an MOCVD reactor chamber. The reactor chamber itself is protected in an inert atmosphere within a glovebox. The reactor is then sealed closed and purged under a flow of nitrogen, argon or hydrogen gas at a rate of 10,000 to 60,000 sccm. The susceptor is rotated at a rate of 40 to 60 rpm. The pressure within the reactor chamber is reduced to 30 to 100 mbar. An optical probe is used to monitor the substrate reflectivity and temperature during growth—with the substrate still in their unheated state, they are rotated under the probe in order to establish a baseline signal. The substrates are then heated using resistive heater coils positioned beneath the susceptor to a setpoint of from 1,000 to 1,500° C. at a rate of 0.1 to 3.0 K/s. The substrates are optionally baked under flow of hydrogen gas for from 10 to 60 min, after which the ambient gas is switched to nitrogen or argon and the pressure is reduced to 30 to 50 mbar. The substrate is annealed at the growth temperature and pressure for a period of from 5 to 10 min, after which a hydrocarbon precursor is admitted to the chamber. This is transported from its liquid state in a bubbler by passing a carrier gas (nitrogen, argon or hydrogen) through the liquid which is held under constant temperature and pressure. The vapour enters a gas mixing manifold and proceeds to the reactor chamber through a showerhead via a multitude of small inlets commonly referred to in the art as plenums/plena, which guarantees uniform vapour distribution and growth across the surface of the substrates. The substrates are exposed to the hydrocarbon vapour under constant flow, pressure and temperature for a duration of 1,800 to 10,800 s at which point the precursor supply valve is shut off. The substrates are then cooled under continuing flow of nitrogen, argon or hydrogen gas at a rate of from 0.1 to 4 K/min. Once the substrates temperature reaches below 200° C., the chamber is pumped to vacuum and purged with inert gas. The rotation is stopped and the heaters are shut off. The reactor chamber is opened and the graphene-coated substrates are removed from the susceptor once the heater temperature reaches below 150° C.

The graphene formed was then characterised using standard techniques including Raman spectroscopy and atomic force microscopy (AFM). The AFM data in FIG. 6 shows the morphology of graphene grown in accordance with the Example using a sapphire wafer onto a thin (<5 nm) alumina layer on aluminium nitride. Rather than growing as discrete strands or flakes of graphene, it grows as a continuous single layer, making it useful for application in electronic devices. When compared to graphene grown directly on aluminium nitride on a sapphire wafer (FIG. 4), the graphene grown even on a thin metal oxide layer exhibits a significantly improved D/G ratio together with improved mobility and carrier scattering time as illustrated by FIGS. 2 and 3.

To create the transistor of FIG. 7, after carrying out the steps described above, a rectangular chip was then scribed out, measuring about 6 mm along one side and about 2 mm on the other. A thin strip of silver paint was applied along the edge of the short (2 mm) sides to form source/drain contacts. The paint was allowed to dry. In a region about 2 mm² in the centre of the chip, a few μL of 10 mM KCl was pipetted onto the graphene surface. An Ag/AgCl pellet reference electrode was dipped into the electrolyte and the potential applied to this acted as the gate voltage.

As used herein, the singular form of “a”, “an” and “the” include plural references unless the context clearly dictates otherwise. The use of the term “comprising” is intended to be interpreted as including such features but not excluding other features and is also intended to include the option of the features necessarily being limited to those described. In other words, the term also includes the limitations of “consisting essentially of” (intended to mean that specific further components can be present provided they do not materially affect the essential characteristic of the described feature) and “consisting of” (intended to mean that no other feature may be included such that if the components were expressed as percentages by their proportions, these would add up to 100%, whilst accounting for any unavoidable impurities), unless the context clearly dictates otherwise.

The foregoing detailed description has been provided by way of explanation and illustration, and is not intended to limit the scope of the appended claims. Many variations of the presently preferred embodiments illustrated herein will be apparent to one of ordinary skill in the art, and remain within the scope of the appended claims and their equivalents.

1. A graphene substrate comprising:
a graphene layer structure directly on a metal oxide layer, said metal oxide layer directly on a support layer;
wherein the metal oxide layer has a thickness of less than 5 nm and is selected from the group consisting of Al₂O₃, HfO₂, MgO, MgAl₂O₄, Ta₂O₅, Y₂O₃, ZrO₂ and YSZ; and
wherein the support layer is BN, AlN, GaN, SiC, diamond, or a combination thereof.

2. The graphene substrate according to claim 1, wherein the support layer is BN, AlN, GaN, or a combination thereof.

3. The graphene substrate according to claim 1, wherein the support layer is provided on a wafer.

4. The graphene substrate according to claim 1, wherein the graphene layer structure is a graphene monolayer.

5. The graphene substrate according to claim 1, wherein the metal oxide layer has a thickness of less than 4 nm.

6. The graphene substrate according to claim 1, wherein the metal oxide layer has a thickness of at least 0.5 nm.

7. The graphene substrate according to claim 1, wherein the support layer has a thickness of at least 5 nm.

8. An electrical device comprising the graphene substrate according to claim 1.

9. A method of forming a graphene substrate, the method comprising:
providing a growth substrate comprising or consisting of a support layer formed of BN, AlN, GaN, SiC, diamond, or a combination thereof;
forming a metal oxide layer on the support layer by ALD, wherein the metal oxide layer has a thickness of less than 5 nm and is selected from the group consisting of Al₂O₃, HfO₂, MgO, MgAl₂O₄, Ta₂O₅, Y₂O₃, ZrO₂ and YSZ; and
forming a graphene layer structure on the metal oxide layer by CVD.

10. The method according to claim 9, wherein the growth substrate further comprises a wafer.

11. The method according to claim 10, wherein the method further comprises etching away or detaching the wafer after forming the graphene layer structure.

12. The method according to claim 9, wherein the method further comprises forming one or more further layers on the graphene layer structure.

13. The method according to claim 12, wherein the method comprises forming a further metal oxide layer on the graphene layer structure by ALD, wherein the further metal oxide layer has a thickness of less than 5 nm and is selected from the group consisting of Al₂O₃, HfO₂, MgO, MgAl₂O₄, Ta₂O₅, Y₂O₃, ZrO₂ and YSZ; and
forming a further layer on the further metal oxide layer, wherein the further layer is BN, AlN, GaN, SiC, diamond, or a combination thereof.
